(19) United States
(12) Patent Application Publication
(10) Pub. No.: US 2009/0243740 A1
(43) Pub. Date: Oct. 1, 2009

(54) METHOD AND SYSTEM FOR REDUCED JITTER SIGNAL GENERATION

(76) Inventor: Ahmadreza Rofougaran, Newport Coast, CA (US)

Correspondence Address: MCANDREWS HELD & MALLOY, LTD, 500 WEST MADISON STREET, SUITE 3400, CHICAGO, IL, 60661, US

(21) Appl. No.: 12/056,487

(22) Filed: Mar. 27, 2008

(51) Int. Cl. H03L 7/099

(52) U.S. Cl. 331/177 R

(57) ABSTRACT

Aspects of a method and system for reduced jitter signal generation are provided. In this regard, an output frequency of an oscillator circuit may be controlled via a digital control word, wherein a least significant bit of the digital control word may control one or more variable capacitors and remaining bits of the digital control word may control one or more banks of fixed capacitors. The least significant bit may be filtered to generate a signal corresponding to an average voltage of the least significant bit. In this regard, the generated signal may be a voltage corresponding to the average voltage of the least significant bit and may control the variable capacitor. The digital control word may be representative of a phase difference between a reference signal and a feedback signal and may be generated via a digital multiplier.

### CROSS-REFERENCE TO RELATED APPLICATIONS/INCORPORATION BY REFERENCE

Not applicable.

### FIELD OF THE INVENTION

Certain embodiments of the invention relate to signal processing. More specifically, certain embodiments of the invention relate to a method and system for reduced jitter signal generation.

### BACKGROUND OF THE INVENTION

The number and types of wireless devices and wireless standards has seen rapid growth in recent years and is unlikely to slow anytime soon. Consequently, available frequency bands, which are regulated by organizations such as the FCC in the USA, are becoming increasingly scarce. Moreover, existing frequency bands are becoming increasingly congested with wireless traffic from the plethora of users and devices in existence. In this regard, designing devices that can reliably operate in such noisy frequency bands is becoming increasingly difficult and costly. Accordingly, efforts exist to develop wireless technologies which operate at higher, less congested frequencies.

However, as frequencies utilized by various wireless technologies and devices continue to increase, signal generation for the processing, transmission, and/or reception of such signals is becoming increasingly challenging for wireless systems designers. In this regard, conventional methods of signal generation, such as integer-N and Fractional-N phase locked loops may be difficult or costly to implement as frequencies increase. For example, traditional signal generation circuits may require complicated and/or expensive tuning. Additionally, traditional signal generation circuits may require large amounts of circuit area. Accordingly, improved methods and systems for generating signals for the processing, transmission, and/or reception of signals up to extremely high frequencies are needed.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method is provided for reduced jitter signal generation, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram illustrating an exemplary phase locked loop (PLL) for reduced jitter signal generation, in accordance with an embodiment of the invention.

FIG. 2 is a flow chart illustrating exemplary steps for generating a reduced jitter signal, in accordance with an embodiment of the invention.

FIG. 3a is a diagram of an exemplary oscillator, in accordance with an embodiment of the invention.

FIG. 3b is a diagram of an exemplary oscillator, in accordance with an embodiment of the invention.

FIG. 3c is a diagram of an exemplary oscillator, in accordance with an embodiment of the invention.

FIG. 4 is a block diagram illustrating an exemplary RF communication device, in accordance with an embodiment of the invention.

### DETAILED DESCRIPTION OF THE INVENTION

Certain embodiments of the invention may be found in a method and system for reduced jitter signal generation. In various embodiments of the invention, an output frequency of an oscillator may be controlled via a digital control word, wherein a least significant bit of the digital control word may control a variable capacitor and remaining bits of the digital control word may control a bank of fixed capacitors. The least significant bit may be filtered or selected so as to generate a signal corresponding to an average voltage of the least significant bit. In this regard, the generated signal may be a voltage corresponding to the average voltage of the least significant bit and the generated voltage may control the variable capacitor. The least significant bit of the digital control word may be delta sigma modulated. The digital control word may be generated, at least in part, via a digital multiplier and may be representative of a phase difference between a reference signal and a feedback signal. In this regard, the feedback signal may be generated by clocking an accumulator at a frequency based on the output frequency of the oscillator. A frequency of a signal generated from the output frequency of the oscillator may be phase locked to a reference frequency.

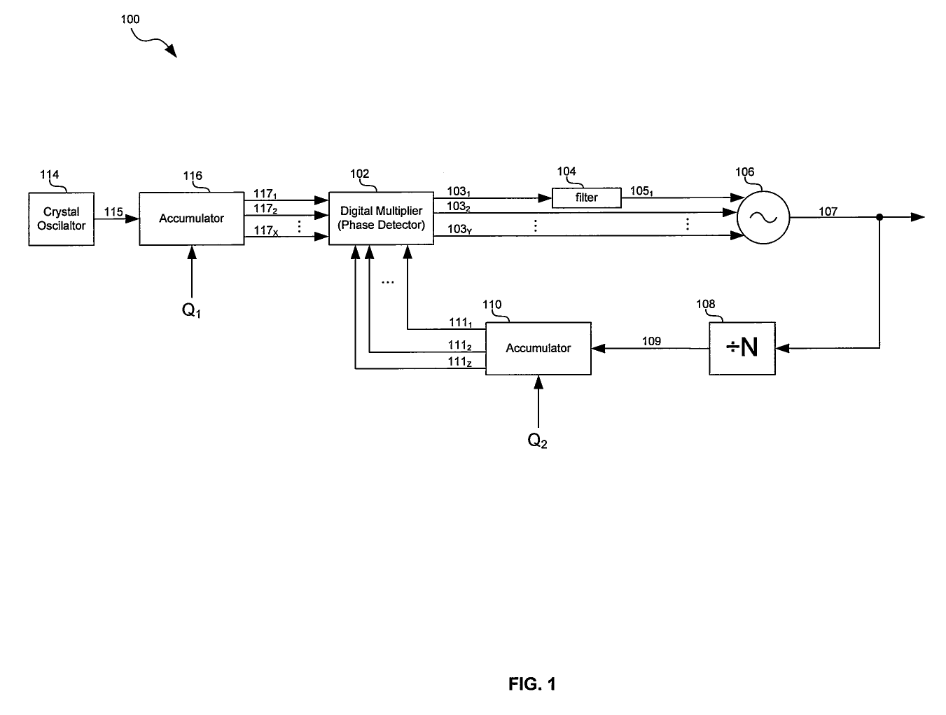

FIG. 1 is a block diagram illustrating an exemplary PLL for reduced jitter signal generation, in accordance with an embodiment of the invention. Referring to FIG. 1 an exemplary PLL 100 may comprise a crystal oscillator 114, an analog-to-digital converter (A/D) 116, a digital multiplier 102, a filter 104, an oscillator 106, a frequency divider 108, and an accumulator 110.

The crystal oscillator 114 may comprise suitable logic, circuitry, and/or code that may enable generating a stable reference frequency.

The accumulator 116 may comprise suitable logic, circuitry, and/or code that may enable successively adding a control word Q1 to a value stored in the accumulator on each cycle of a reference clock. The accumulator 116 may receive the control word Q₁, and a reference signal. In this regard, the control word Q₁, and the reference signal may determine a phase and/or a frequency of the output signal 117. In an exemplary embodiment of the invention, the accumulator 116 may be clocked by the crystal oscillator 114. The control word Q₁ may be successively added to a value stored in the accumulator 116 on each cycle of the signal 115. In this manner, the sum may eventually be greater than the maximum value the accumulator may store, and the value in the accumulator may overflow or “wrap”. Accordingly, an n-bit accumulator may overflow at a frequency fₒ given by EQ. 1.

f₁₁₆=f₁₁₅(Q₁/2ⁿ) EQ.1

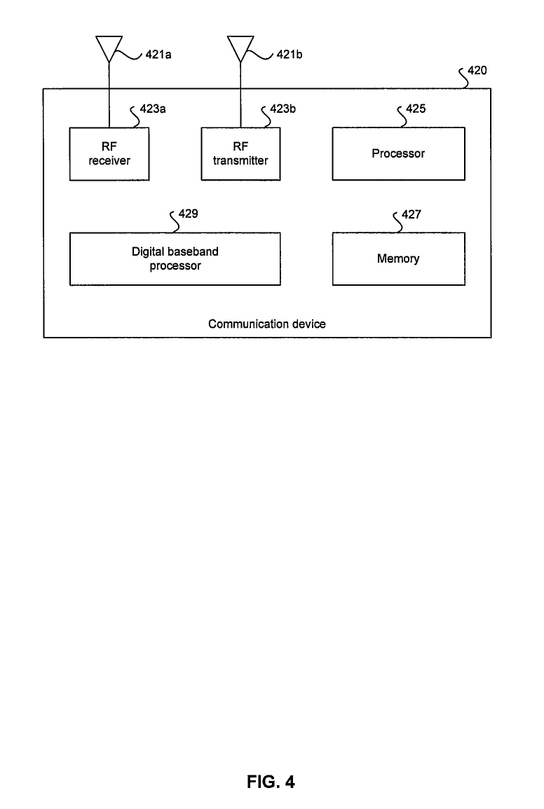

In this manner, the output of the accumulator 116 may be periodic with period 1/f₁₁₆. Additionally, the control word, Q₁, may be provided by, for example, the processor 425 of FIG. 4. In this regard, possible values of the control word may be generated based on possible values of the reference frequency 115 and the desired frequency of the signal 107. Values of the control word Q₂ may be stored in, for example, a look up table in the memory 427 of FIG. 4.

The digital multiplier 102 may comprise suitable logic, circuitry, and/or code that may enable multiplying the digital signals 111 and 117 and outputting the product via 103₁, . . . , 103_{y}. An average value of the product of the signals 111 and 117 may be utilized to determine a phase difference between the signals 111 and 117. In this regard, an average product of 0 may indicate the signals 111 and 117 are in-phase, while a non-zero average product may indicate a phase difference between the signals 111 and 117. Accordingly, in instances where the average product of the signals 111 and 117 is not 0, then the signal 103 may be adjusted until the average product is 0, at which point the signal 103 may stabilize. However, due to the resolution of the digital multiplier 102, an exact phase lock may lie in between two successive values of the control word 103 which may result in the LSB 103₁ toggling between high and low. Thus, controlling the oscillator 106 with 103₁ may result in jitter on the output signal 107.

The filter 104 may comprise suitable logic, circuitry and/or code that may enable filtering the least significant bit 103₁. In an exemplary embodiment of the invention, the signal 105₁ output by the filter 104 may correspond to an average value of the signal 103₁. In this manner, jitter and/or noise in the signal 103₁, and thus in the output signal 107, may be reduced. For example, the filter 104 may integrate the signal 103₁ and the signal 105₁ may be a voltage which may correspond to an average voltage of the signal 103₁. Additionally, in various embodiments of the invention, the voltage of signal 105₁ may be level shifted, scaled, or otherwise conditioned so as to provide an appropriate control voltage to a varactor in the oscillator 106.

The oscillator 106 may comprise suitable logic, circuitry, and/or code that may enable generating a signal 107 based on signals 103 and 105. In this regard, the frequency of the signal 107 may be determined, at least in part, by the digital control word 103 and analog signal 105. In an exemplary embodiment of the invention, the digital signal 103 may enable a quick and/or course frequency control and the analog signal 105 may enable a fine frequency control.

The frequency divider 108 may comprise suitable logic, circuitry, and/or code for receiving a first, higher frequency and outputting a second, lower frequency. The scaling factor, N, may be determined based on one or more control signals from, for example, the processor 425 of FIG. 4. In this regard, values for the frequency divider may be stored in, for example, a look-up table in the memory 427 of FIG. 4.

The accumulator 110 may comprise suitable logic, circuitry, and/or code that may enable successively adding a digital control word Q₂ to a value stored in the accumulator on each cycle of a reference clock. The accumulator may receive the control word Q₂ and a reference signal. In this regard, the control word Q₂ and the reference signal may determine a phase and/or a frequency of the output signal 111. In an exemplary embodiment of the invention, the accumulator may be clocked by the VCO output 107, or, as depicted in FIG. 1, the signal 109 which may be a divided down version of the VCO output 107. The control word Q may be successively added to a value stored in the accumulator on each cycle of the reference clock. In this manner, the sum may eventually be greater than the maximum value the accumulator 110 may store, and the value in the accumulator may overflow or “wrap”. Accordingly, an N-bit accumulator may overflow at a frequency fₒ given by EQ. 2.

f₁₁₀=f₁₀₉(Q₂/2ⁿ) EQ.2

In this manner, the output of the accumulator 110 may be periodic with period 1/f₁₁₀. Additionally, the control word, Q₂, may be provided by, for example, the processor 425 of FIG. 4. In this regard, possible values of the control word may be stored in, for example, a look up table in the memory 427 of FIG. 4.

In operation the PLL 100 may generate a signal 107 based on the fixed frequency reference signal 115 from the crystal oscillator 114. In this regard, the accumulator 110 may enable generating, based on the signal 109 and the control word Q₂, a digital signal 111. The signal 111 may provide feedback such that the oscillator 106 may generate a signal of varying frequency while having the stability of the fixed frequency crystal oscillator 114. In this regard, the multiplier 102 may compare the phase of the signal 117 to the phase of the signal 111 and generate an error signal 103 indicative of the phase difference between the signals 111 and 117. The error signal 103 may be a digital signal comprising one or more bits.

The least significant bit 103₁ may be filtered, integrated, and/or otherwise processed so as to obtain the signal 105₁ which may correspond to the average value of the signal 103₁. The signals 103₂, . . . , 103_{N} and 105₁ may control a capacitance, and thus a frequency, of the oscillator 107. In this manner, the phase error between the signal 111 and the signal 117 may be maintained within determined limits. Accordingly, the output signal 107 of the oscillator 106 may be any integer multiple or fractional multiple of the reference signal 115. In this regard, the signal 111 may be determined using

$${f}_{111} = \frac{{f}_{107}}{N} \cdot {Q}_{2} \cdot \frac{1}{{2}^{n}} \qquad EQ . 3$$

where f₁₁₁ is the frequency of the signal 111, f₁₀₇ is the frequency of the signal 107, N is the divide ratio of the frequency divider 108, Q₂ is the value of the control word input to the accumulator 110, and ‘n’ is the number of bits of the accumulator 110. Accordingly, the PLL 100 may be enabled to generate a wide range of frequencies, with high resolution, without the need of a traditional fractional-N synthesizer.

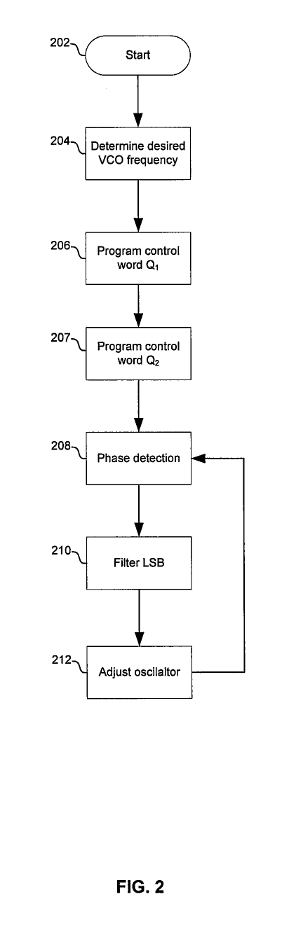

FIG. 2 is a flow chart illustrating exemplary steps for generating a reduced jitter signal, in accordance with an embodiment of the invention. Referring to FIG. 2, the exemplary steps may begin with start step 202. Subsequent to start step 202, the exemplary steps may advance to step 204. In step 204, a desired frequency to be output by the oscillator 106 may be determined. In this regard, in instances that the PLL 100 may be utilized to transmit or receive RF signals, then the output of the oscillator 106 may be determined based on the RF transmit and/or RF receive frequency. Subsequent to step 204, the exemplary steps may advance to step 206. In step 206, the digital control word Q₁ input to the accumulator 116 may be determined. In this regard, the value of the digital control word Q₁ may be determined based on a desired reference frequency of the signal 117. Subsequent to step 206, the exemplary steps may advance to step 207. In step 207, the digital control word Q₂ input to the accumulator 110 may be determined. In this regard, the value of the digital control word Q₂ may be determined utilizing EQ. 3 above. Accordingly, for different values of the reference frequency 115 and/or the desired output frequency 107, the value of the digital control word may be adjusted. In this regard, a processor, such as the processor 425 or the processor 529 of FIG. 4, may programmatically control the value of the digital control word.

Subsequent to step 206, the exemplary steps may advance to step 208. In step 208, a phase difference between the signal 111 and the signal 117 may be determined. The phase difference may be determined by multiplying the signals 111 and 117. In this regard, the average value of the product of the signals 111 and 117 may be indicative of a phase difference between the signals 111 and 117. Subsequent to step 208, the exemplary steps may advance to step 210. In step 210, the least significant bit of the digital control word 103, may be filtered to generate the signal 105₁. In this manner, 105₁ may correspond to the average value of the signal 103₁. Subsequent to step 210, the exemplary steps may advance to step 212. In step 212, the oscillator 106 may be adjusted based on the phase difference between the signals 111 and 117. For example, a capacitance coupled to an output node of the oscillator 106 may be adjusted such that the phase difference between the signals 111 and 117 may be reduced. In this regard, the capacitance may comprise a bank of capacitors controlled via the signals 103₂, . . . , 103_{N}, and one or more varactors controlled via the signal 105₁. Accordingly, when there may be no phase difference between the signals 111 and 117 the signals 103 and 105 may stabilize and the PLL may be “locked”. Subsequent to step 210, the exemplary steps may return to step 208. In this regard, maintaining phase lock may be a continuous process that requires periodic or even constant feedback.

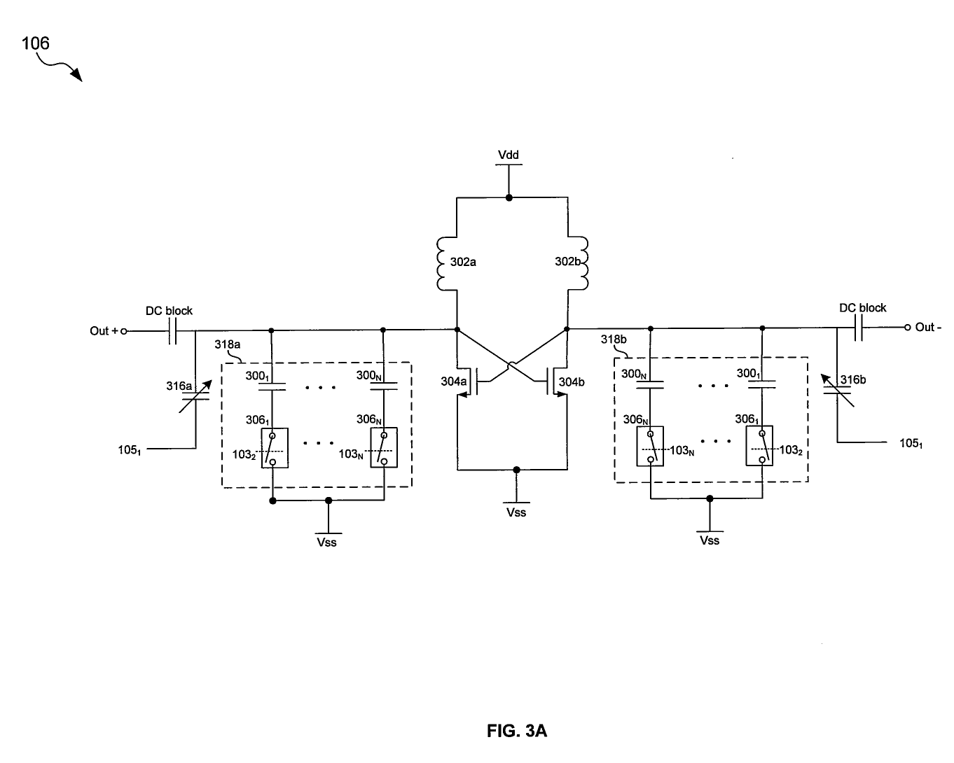

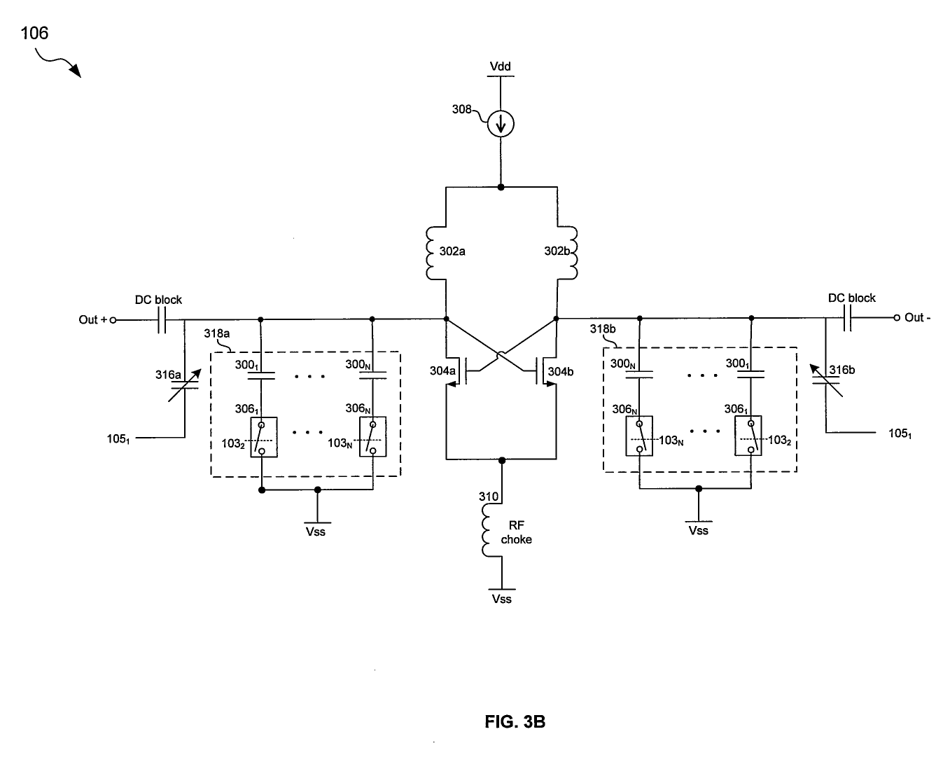

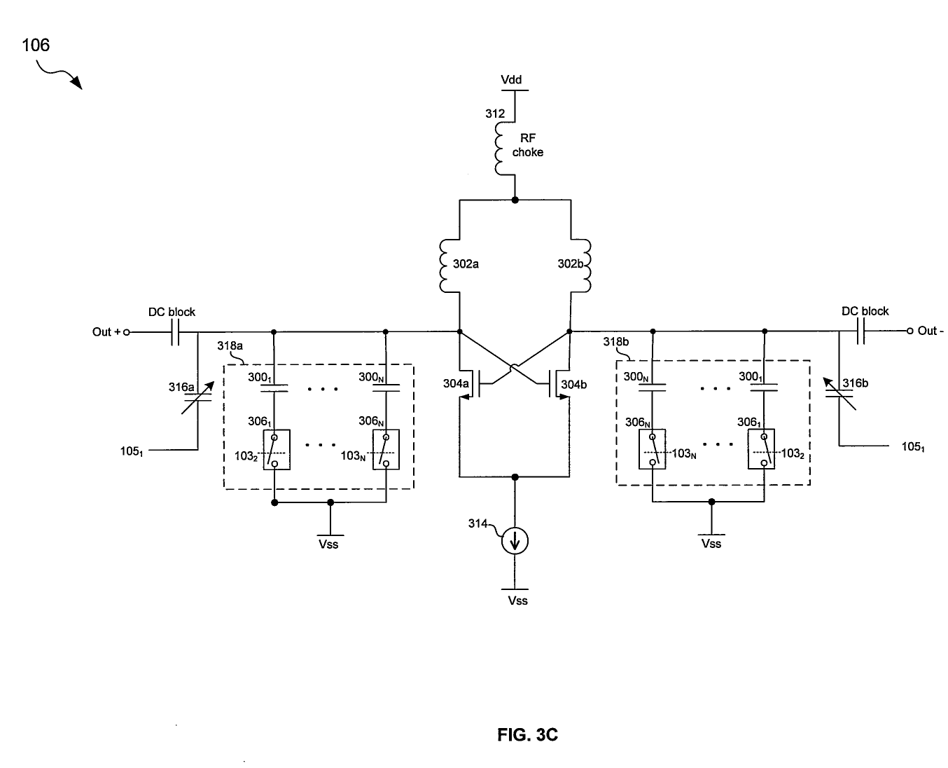

FIG. 3a is a diagram of an exemplary oscillator, in accordance with an embodiment of the invention. Referring to FIG. 3a there is shown an exemplary oscillator 106 which may comprise capacitor banks 318, varactors 316, a pair of transistors 304, and a pair of inductors 302. The capacitor banks 318 may comprise one or more capacitances 300 and one or more switching elements 306.

In various embodiments of the invention, the varactors 316 may comprise diodes for which a junction capacitance determined by a reverse bias voltage applied to the diodes.

In various embodiments of the invention, the signal 103 described with respect to FIG. 1 may comprise N bits, where N may be an integer greater than 0. Accordingly, the capacitor banks 318 may be controlled via the N-1 most significant bits of the digital control word 103 and the varactors 316 may be controlled via the signal 105₁, which may correspond to an average voltage of the least significant bit of the digital control word 103.

In operation, the switching elements 306 may enable coupling and decoupling the capacitors 300 to the output nodes “out+” and/or “out−”. Accordingly, depending on the value of the digital signal(s) 103₂, . . . , 103_{N}, one or more capacitances 300 may be coupled or decoupled from the output nodes and thus alter the frequency of oscillation of the outputs. In various embodiments of the invention, the signal 103 may be delta sigma modulated and thus an effective capacitance of the capacitor banks 318 at the output nodes may depend on factors such as switching frequency and duty cycle of the signal 103.

FIG. 3b is a diagram of an exemplary oscillator, in accordance with an embodiment of the invention. In this regard, FIG. 3b depicts an alternative to the embodiment illustrated in FIG. 3a. Referring to FIG. 3b there is shown an exemplary oscillator 106 which may comprise capacitor banks 318, varactors 316, a pair of transistors 304, a pair of inductors 302, a current source 308, and an RF choke 310.

The capacitors banks 318, varactors 316, transistors 304, and inductors 302 may be as described in FIG. 3a. The current source 308 may comprise suitable logic, circuitry, and/or code for supplying a constant (within a tolerance) current. The RF choke 310 may enable sinking DC current to GND while impeding AC current. The oscillator of FIG. 3b may enable alternative biasing arrangements as compared to the oscillator of FIG. 3a. Accordingly, choosing one embodiment or the other may provide flexibility when designing the PLL 100.

FIG. 3c is a diagram of an exemplary oscillator, in accordance with an embodiment of the invention. In this regard, FIG. 3c depicts an alternative to the embodiments illustrated in FIGS. 3a and 3b. Referring to FIG. 3b there is shown an exemplary oscillator 106 which may comprise capacitor banks 318, varactors 316, a pair of transistors 304, a pair of inductors 302, a current source 308, and an RF choke 310.

The capacitors banks 318, varactors 316, transistors 304, and inductors 302 may be as described in FIG. 3a. The RF choke 312 may enable passing DC current from VDD while impeding AC current. The current source 314 may comprise suitable logic, circuitry, and/or code for sinking a constant (within determined limits) current. The oscillator of FIG. 3c may enable alternative biasing arrangements as compared to the oscillators of FIG. 3a and FIG. 3b. Accordingly, choosing between the various embodiments may provide flexibilty when designing the PLL 100.

FIG. 4 is a block diagram illustrating an exemplary RF communication device, in accordance with an embodiment of the invention. Referring to FIG. 4, there is shown a RF communication device 420 that may comprise an RF receiver 423a, an RF transmitter 423b, a digital baseband processor 429, a processor 425, and a memory 427. A receive antenna 421a may be communicatively coupled to the RF receiver 423a. A transmit antenna 421b may be communicatively coupled to the RF transmitter 423b. The RF communication device 420 may be operated in a system, such as the cellular network and/or digital video broadcast network, for example.

The RF receiver 423a may comprise suitable logic, circuitry, and/or code that may enable processing of received RF signals. In this regard, the receiver may be enabled to generate signals, such as local oscillator signals, for the reception and processing of RF signals. The RF receiver 423a may down-convert received RF signals to a baseband frequency signal. The RF receiver 423a may perform direct down-conversion of the received RF signal to a baseband frequency signal, for example. In some instances, the RF receiver 423a may enable analog-to-digital conversion of the baseband signal components before transferring the components to the digital baseband processor 429. In other instances, the RF receiver 423a may transfer the baseband signal components in analog form.

The digital baseband processor 429 may comprise suitable logic, circuitry, and/or code that may enable processing and/or handling of baseband frequency signals. In this regard, the digital baseband processor 429 may process or handle signals received from the RF receiver 423a and/or signals to be transferred to the RF transmitter 423b. The digital baseband processor 429 may also provide control and/or feedback information to the RF receiver 423a and to the RF transmitter 423b based on information from the processed signals. In this regard, the baseband processor 429 may provide one or more control signals to, for example, the accumulator 114, the multiplier 102, the filter 104, the oscillator 106, the frequency divider 108, and/or the accumulator 110. The digital baseband processor 429 may communicate information and/or data from the processed signals to the processor 425 and/or to the memory 427. Moreover, the digital baseband processor 429 may receive information from the processor 425 and/or to the memory 427, which may be processed and transferred to the RF transmitter 423b for transmission to the network.

The RF transmitter 423b may comprise suitable logic, circuitry, and/or code that may enable processing of RF signals for transmission. In this regard, the transmitter may be enabled to generate signals, such as local oscillator signals, for the transmission and processing of RF signals. The RF transmitter 423b may up-convert the baseband frequency signal to an RF signal. The RF transmitter 423b may perform direct up-conversion of the baseband frequency signal to a RF signal, for example. In some instances, the RF transmitter 423b may enable digital-to-analog conversion of the baseband signal components received from the digital baseband processor 429 before up conversion. In other instances, the RF transmitter 423b may receive baseband signal components in analog form.

The processor 425 may comprise suitable logic, circuitry, and/or code that may enable control and/or data processing operations for the RF communication device 420. The processor 425 may be utilized to control at least a portion of the RF receiver 423a, the RF transmitter 423b, the digital baseband processor 429, and/or the memory 427. In this regard, the processor 425 may generate at least one signal for controlling operations within the RF communication device 420. In this regard, the baseband processor 429 may provide one or more control signals to, for example, the accumulator 114, the multiplier 102, the filter 104, the oscillator 106, the frequency divider 108, and/or the accumulator 110. The processor 425 may also enable executing of applications that may be utilized by the RF communication device 420. For example, the processor 425 may execute applications that may enable displaying and/or interacting with content received via RF signals in the RF communication device 420.

The memory 427 may comprise suitable logic, circuitry, and/or code that may enable storage of data and/or other information utilized by the RF communication device 420. For example, the memory 427 may be utilized for storing processed data generated by the digital baseband processor 429 and/or the processor 425. The memory 427 may also be utilized to store information, such as configuration information, that may be utilized to control the operation of at least one block in the RF communication device 420. For example, the memory 427 may comprise information necessary to configure the RF receiver 423a to enable receiving signals in the appropriate frequency band. In this regard, the memory 427 may store configuration and/or control information for the accumulator 114, the multiplier 102, the filter 104, the oscillator 106, the frequency divider 108, and/or the accumulator 110.

Aspects of a method and system for reduced jitter signal generation are provided. In this regard, an output frequency of an oscillator, such as the oscillator 106, may be controlled via a digital control word, such as the digital control word 103. A least significant bit of the digital control word 103 may control one or more variable capacitors, such as the capacitor 316a and/or 316b, and remaining bits of the digital control word may control one or more banks of fixed capacitors, such as the capacitor bank 318a and/or 318b. The least significant bit may be filtered, for example utilizing the filter 104, to generate a signal corresponding to an average voltage of the least significant bit. In this regard, the generated signal may be a voltage corresponding to the average voltage of the least significant bit and the generated voltage may control the variable capacitor. The least significant bit of the digital control word 103 may be delta sigma modulated. The digital control word 103 may be may be generated, at least in part, via a digital multiplier, such as the multiplier 102, and may be representative of a phase difference between a reference signal, such as the signal 117, and a feedback signal, such as the signal 111. In this regard, the feedback signal may be generated by clocking an accumulator, such as the accumulator 110, at a frequency based on the output frequency of the oscillator 106. A frequency of a signal, such as the signal 111, generated from the output frequency of the oscillator 106 may be phase locked to a reference frequency.

Another embodiment of the invention may provide a machine-readable storage, having stored thereon, a computer program having at least one code section executable by a machine, thereby causing the machine to perform the steps as described herein for reduced jitter signal generation.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for signal processing, the method comprising:
controlling an output frequency of an oscillator circuit via a digital control word, wherein a least significant bit of said digital control word controls a variable capacitor in said oscillator circuit and remaining bits of said digital control word control a bank of fixed capacitors in said oscillator circuit.

2. The method according to claim 1, comprising filtering said least significant bit to generate a signal corresponding to an average voltage of said least significant bit.

3. The method according to claim 2, comprising filtering said least significant bit to generate a voltage corresponding to an average voltage of said least significant bit.

4. The method according to claim 3, comprising controlling said variable capacitor via said voltage.

5. The method according to claim 1, comprising delta sigma modulating said least significant bit of said digital control word.

6. The method according to claim 1, wherein said digital control word is representative of a phase difference between a reference signal and a feedback signal.

7. The method according to claim 6, comprising clocking an accumulator at a frequency based on said output frequency of said oscillator circuit to generate said feedback signal.

8. The method according to claim 6, comprising generating said digital control word via a digital multiplier.

9. The method according to claim 1, comprising phase locking a frequency generated from said output frequency of said oscillator to a reference frequency.

10. A machine-readable storage having stored thereon, a computer program having at least one code section for signal processing, the at least one code section being executable by a machine for causing the machine to perform steps comprising:
controlling an output frequency of an oscillator circuit via a digital control word, wherein a least significant bit of said digital control word controls a variable capacitor in said oscillator circuit and remaining bits of said digital control word control a bank of fixed capacitors in said oscillator circuit.

11. The machine-readable storage according to claim 10, wherein said at least one code section comprises code that enables filtering said least significant bit to generate a signal corresponding to an average voltage of said least significant bit.

12. The machine-readable storage according to claim 11, wherein said at least one code section comprises code that enables filtering said least significant bit to generate a voltage corresponding to an average voltage of said least significant bit.

13. The machine-readable storage according to claim 12, wherein said at least one code section comprises code that enables controlling said variable capacitor via said voltage.

14. The machine-readable storage according to claim 10, wherein said at least one code section comprises code that enables delta sigma modulating said least significant bit of said digital control word.

15. The machine-readable storage according to claim 10, wherein said digital control word is representative of a phase difference between a reference signal and a feedback signal.

16. The machine-readable storage according to claim 15, wherein said at least one code section comprises code that enables clocking an accumulator at a frequency based on said output frequency of said oscillator circuit to generate said feedback signal.

17. The machine-readable storage according to claim 15, wherein said at least one code section comprises code that enables generating said digital control word via a digital multiplier.

18. The machine-readable storage according to claim 10, wherein said at least one code section comprises code that enables phase locking said output frequency of said oscillator to a reference frequency.

19. A system for signal processing, the system comprising:
one or more circuits comprising an oscillator circuit, wherein said one or more circuits enable control of an output frequency of said oscillator circuit via a digital control word, and a least significant bit of said digital control word controls a variable capacitor in said oscillator circuit and remaining bits of said digital control word control a bank of fixed capacitors in said oscillator circuit.

20. The system according to claim 19, wherein said one or more circuits comprise one or more filters that enable filtering said least significant bit to generate a signal corresponding to an average voltage of said least significant bit.

21. The system according to claim 20, wherein said one or more circuits comprise one or more filters that enable filtering said least significant bit to generate a voltage corresponding to an average voltage of said least significant bit.

22. The system according to claim 21, wherein said one or more circuits enable control of said variable capacitor via said voltage.

23. The system according to claim 19, wherein said one or more circuits comprise a delta sigma modulator that enables processing said least significant bit of said digital control word.

24. The system according to claim 19, wherein said digital control word is representative of a phase difference between a reference signal and a feedback signal.

25. The system according to claim 24, wherein said one or more circuits comprise an accumulator clocked at a frequency based on said output frequency of said oscillator circuit to generate said feedback signal.

26. The system according to claim 24, wherein said one or more circuits comprise a digital multiplier that enables generation of said digital control word.

27. The system according to claim 19, wherein said one or more circuits enable phase locking a frequency generated from said output frequency of said oscillator to a reference frequency.
